(19) United States
(12) Patent Application Publication
(10) Pub. No.: US 2010/0187666 A1
(43) Pub. Date: Jul. 29, 2010

(54) LEAD FRAME AND METHOD OF MANUFACTURING SEMICONDUCTOR DEVICE

(75) Inventor: Koji YAMADA, Kawasaki-shi (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki-shi (JP)

(21) Appl. No.: 12/686,884

(22) Filed: Jan. 13, 2010

(30) Foreign Application Priority Data
Jan. 29, 2009 (JP) 2009-017648

(51) Int. Cl. H01L 23/495; H01L 21/98

(52) U.S. Cl. 257/676; 438/109; 438/123; 257/666; 257/E23.043; 257/E21.705

(57) ABSTRACT

A lead frame includes a welding portion to be welded to other lead frame, and a frame, wherein the welding portion has an island portion provided like an island, and a plurality of connection members which connect the island portion and the frame with each other; and one connection member is provided so that a straight line which connects a connection point of the island portion and one connection member, and a connection point of one connection member and the frame, inclines away from a portion of the outer circumference (edge, for example) of the island portion where the connection member is connected, and also from a portion of the inner circumference (edge, for example) of the frame where the connection member is connected.

This application is based on Japanese patent application No. 2009-017648 the content of which is incorporated hereinto by reference.

### BACKGROUND

1. Technical Field

The present invention relates to a lead frame and a method of manufacturing a semiconductor device.

2. Related Art

General lead frame used in a form of being welded after two-ply stacked is disclosed in Japanese Laid-Open Patent Publication No. H09-082875 and H11-260995.

Such lead frame has a frame and welding portions. Welding portions are used for the convenience of welding two lead frames with each other after stacking them. Each welding portion is configured to have an island portion, and a plurality of connection members which connect the island portion with the frame, so as to make the frame support the island portion just like suspending it. Each connection member is formed, for example, into an S-shape.

It has been difficult to fully suppress the stress ascribable to thermal expansion of the island portion owned by the welding portion of the lead frame from propagating through the connection members to the frame, and to suppress deformation of the lead frames.

### SUMMARY

According to the present invention, there is provided a lead frame which include a welding portion to be welded to other lead frame, and a frame. The welding portion has an island portion provided like an island, and a plurality of connection members which connect the island portion and the frame with each other. One connection member is provided so that a straight line which connects a connection point of island portion and such one connection member, and a connection point of such one connection member and the frame, inclines away from at least either of a portion of the outer circumference of the island portion where such one connection member is connected, and a portion of the inner circumference of the frame where such one connection member is connected.

Referring to the configuration of the lead frame 100 (described later) illustrated in FIG. 16 and FIG. 17, the direction of a straight line 115 which connects “a connection point 113 of the connection member 112 and the island portion 111” and “a connection point 114 of the connection member 112 and the frame 103”, illustrated in FIG. 17, coincides with the direction of deformation from the island portion 111 to the post-thermal-expansion island portion 141, indicated by arrows in FIG. 21. In other words, the straight line 115 is normal to each edge 116 (FIG. 17) which composes the outer circumference of the island portion 111, and also to each edge 118 (FIG. 17) which composes the inner circumference of the frame 103. As a consequence, stress ascribable to deformation of the island portion 111 in the process of welding may propagate through the connection members 112 to the frame 103, and may deform the frame 103.

In contrast, in the lead frame of the present invention, the straight line which connects a connection point of island portion and one connection member, and a connection point of such one connection member and the frame, inclines away from at least either of a portion of the outer circumference of the island portion where such one connection member is connected, and a portion of the inner circumference of the frame where such one connection member is connected. Accordingly, the stress ascribable to thermal expansion of the island portion in the process of welding may be absorbed by deflection of the connection members. In other words, the stress may be absorbed by the deformation of the connection members in the direction which crosses the straight line at a certain angle (in the normal direction, for example). As a consequence, the stress possibly propagating to the frame may be moderated, and thereby the overall deformation of the lead frame, excluding the welding portions, may be suppressed.

According to the present invention, there is also provided a method of manufacturing a semiconductor device, the method includes: a first step mounting semiconductor elements respectively on the die pads of a first lead frame and a second lead frame, each of which is the lead frame of the present invention; a second step stacking the first and second lead frames, so that the welding portions are aligned with each other, to thereby obtain a two-ply stack; and a third step welding the welding portions thus stacked in the second step.

According to the present invention, the stress ascribable to thermal expansion of the island portions owned by the welding portions of the lead frame may fully be suppressed from propagating through the connection members to the frame, and thereby deformation of the lead frame may be suppressed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view illustrating a lead frame of a first embodiment;

FIG. 2 is an enlarged plan view of the welding portion owned by the lead frame of the first embodiment;

FIG. 3 is a plan view illustrating a state of stacking of the lead frames of the first embodiment;

FIG. 4 is a sectional side elevation illustrating a state of mutually welding the lead frames of the first embodiment;

FIG. 5 is a plan view illustrating a state of thermal expansion of the island portion of the lead frame of the first embodiment, in the process of welding;

FIG. 6 is a plan view explaining a behavior of a welding portion when the island portion of the lead frame of the first embodiment causes thermal expansion in the process of welding;

FIG. 7 is an enlarged plan view illustrating a welding portion of a lead frame of a second embodiment;

FIG. 8 is an enlarged plan view illustrating a welding portion of a lead frame of a third embodiment;

FIG. 9 is an enlarged plan view illustrating a welding portion of a lead frame of a fourth embodiment;

FIG. 10 is an enlarged plan view illustrating a welding portion of a lead frame of a fifth embodiment;

FIG. 11 is an enlarged plan view illustrating a welding portion of a lead frame of a sixth embodiment;

FIG. 12 is an enlarged plan view illustrating a welding portion of a lead frame of a seventh embodiment;

FIG. 13 is an enlarged plan view illustrating a welding portion of a lead frame of a eighth embodiment;

FIG. 14 is an enlarged plan view illustrating a welding portion of a lead frame of a ninth embodiment;

FIG. 15 is an enlarged plan view illustrating a welding portion of a lead frame of a tenth embodiment;

FIG. 16 is a plan view illustrating a comparative example of a lead frame used after being welded in a form of two-ply stack;

FIG. 17 is an enlarged plan view illustrating a welding portion owned by the lead frame illustrated in FIG. 16;

FIG. 18 is a plan view illustrating a state of stacking of the lead frames illustrated in FIG. 16;

FIG. 19 is a sectional side elevation illustrating a state of welding of the lead frames illustrated in FIG. 16;

FIG. 20 is a plan view illustrating a state of thermal expansion of the island portion of the lead frame illustrated in FIG. 16, in the process of welding; and

FIG. 21 is a plan view illustrating a state of deformation of the frame, due to thermal expansion of the island portion of the lead frame illustrated in FIG. 16.

### DETAILED DESCRIPTION

Before describing of the present invention, the related art will be explained in detail with reference to FIG. 16 to FIG. 21 in order to facilitate the understanding of the present invention.

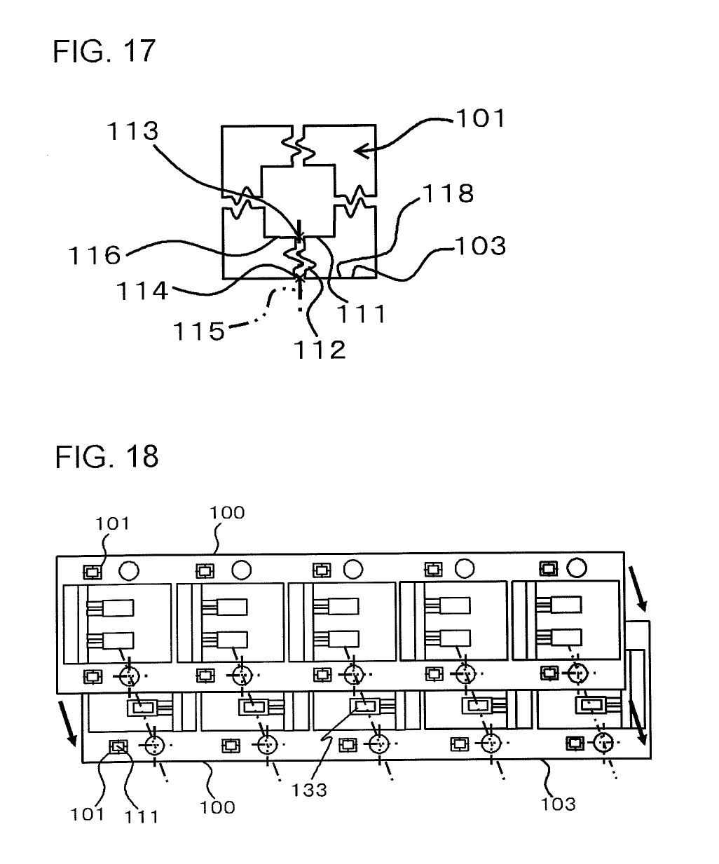

FIG. 16 is a plan view illustrating a comparative example of a lead frame 100 used in a form of being welded after two-ply stacked, and FIG. 17 is an enlarged plan view illustrating a welding portion 101 owned by the lead frame 100 illustrated in FIG. 16.

As illustrated in FIG. 16, the lead frame 100 is configured to have a semiconductor device configuring portions 102 each of which configures a part of a semiconductor device, and a frame 103.

Each semiconductor device configuring portion 102 is configured to have die pads 104, leads 105, and a tie bar 106.

Each semiconductor device configuring portion 102 has, for example, two die pads 104. Each die pad 104 is connected to the tie bar 106 through, for example, two leads 105.

The thus-configured lead frame 100 has welding portions 101, for the convenience of welding two lead frames 100 with each other after stacking them. The welding portions 101 are provided so as to be contained in the frame 103, but not in the semiconductor device configuring portion 102.

As illustrated in FIG. 17, each welding portion 101 is configured to have an island portion 111, and a plurality of connection members 112 which connect the island portion 111 with the frame 103, so as to make the frame 103 support the island portion 111 just like suspending it. Each connection member 112 is formed, for example, into an S-shape.

In the welding portion 101 configured as illustrated in FIG. 17, a straight line 115 which connects “a connection point 113 of the connection member 112 and the island portion 111” and “a connection point 114 of the connection member 112 and the frame 103” is normal to one edge 116 of the outer circumference of the island portion 111, to which the connection member 112 is connected. The straight line 115 is normal also to one edge 118 of the inner circumference of the frame 103, to which the connection member 112 is connected.

Next, a method of manufacturing the semiconductor device manufactured using the lead frames 100 illustrated in FIG. 16 will be explained. The description herein will deal with an exemplary case where a photo-coupler is manufactured as one example of a semiconductor device.

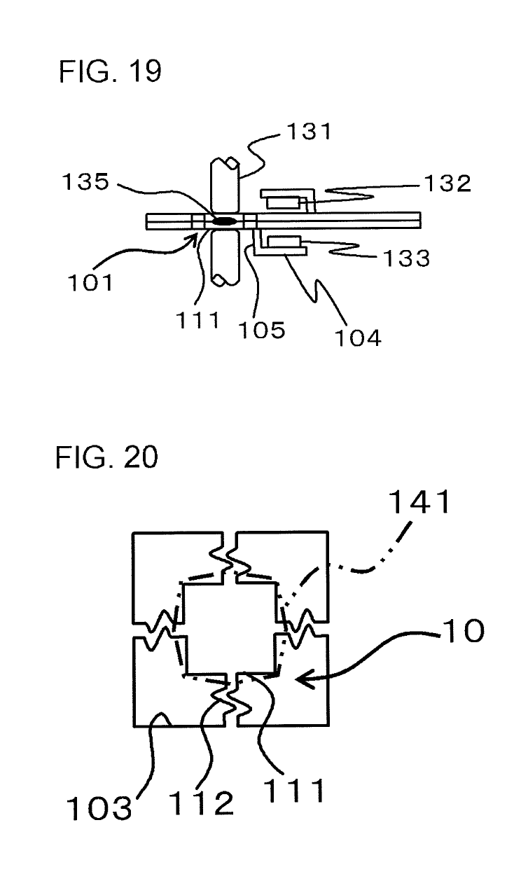

FIG. 18 is a plan view illustrating a state of stacking two lead frames 100, and FIG. 19 is a sectional side elevation illustrating a process of welding two lead frames 100.

First, light emitting elements 132 (see FIG. 19) are mounted on the individual die pads 104 of one of two lead frames 100 to be bonded with each other, and light receiving elements 133 (see FIG. 19) are mounted on the individual die pads 103 of the other lead frame 100.

Each light emitting element 132 and each light receiving element 133 are necessarily opposed while keeping a space therebetween (see FIG. 19). For this reason, the leads 105 which connect the individual die pads 104 to the tie bars 106 are preliminarily bent for making offset (see FIG. 19), before the light emitting elements 132 or the light receiving elements 133 are mounted on the die pads 104.

Next, as illustrated in FIG. 18 and FIG. 19, two lead frames 100 are stacked so as to align the correspondent welding portions 101.

Next, as illustrated in FIG. 19, a pair of welding electrodes 131 are brought into contact with a pair of island portions 111 so as to supply current therethrough, to thereby effect resistance welding. In the process of current supply, a weld nugget 135 is formed between the pair of island portions 111 stacked with each other, by Joule heat generated in the island portions 111, and thereby the pair of island portions 111 are bonded with each other.

For the case where the semiconductor device is a photo-coupler, it may be necessary to minimize misalignment of the light emitting element 132 and the light receiving element 133, in order to ensure a satisfactory level of coupling efficiency of light. It is also important to minimize overall deformation of the lead frames 100 after being welded, in order to avoid non-conformities in assembly such as unsuccessful feeding and so forth, in view of improving the productivity.

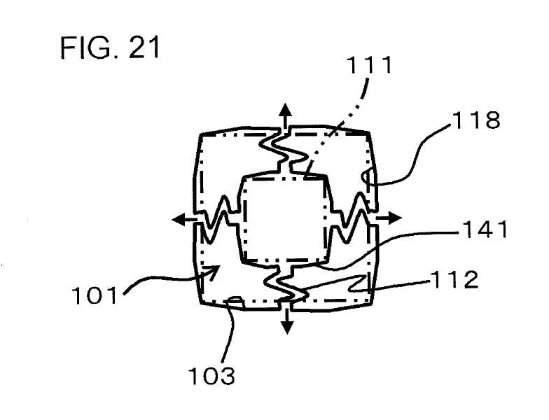

FIG. 20 is a plan view illustrating a state of thermal expansion of the island portion 111 of the lead frame 100 due to welding, and FIG. 21 is a plan view illustrating a state of deformation of the frame 103 due to the thermal expansion of the island portion 111.

The island portion 111 of the lead frame 100 causes thermal expansion, due to Joule heat generated in the process of welding, and deforms so as to spread itself. More specifically, the island portion 111 deforms, by thermal expansion, typically from a geometry indicated by a solid line to a geometry indicated by a two-dot chain line (a post-thermal-expansion island portion, denoted by reference numeral 141) illustrated in FIG. 20.

In the process of deformation from the island portion 111 to the post-thermal-expansion island portion 141, the island portion 111 pushes the connection members 112 outward, and the thus-pushed connection members 112 outwardly expand the frame 103, as illustrated in FIG. 21. Since stress ascribable to the deformation of the island portion 111 propagates through the connection members 112 to the frame 103 in this way, so that the lead frame 100 may deform over the entire range thereof. As a consequence, the light emitting element 132 and the light receiving element 133 may cause misalignment, and this may, for example, undesirably degrade coupling efficiency of light in the photo-coupler, cause non-conformities in assembly such as unsuccessful feeding and so forth, and distinctively degrade the productivity of the photo-coupler.

Note that, as illustrated in FIG. 17, stress ascribable to the deformation of the welding portions 101 is suppressed from directly propagating to the frame 103 to a certain extent, by virtue of the structure having the island portion 111 provided to the welding portion 101, so as to be connected to the frame 103 just as being suspended by the connection members 112. The lead frame 100 illustrated in FIG. 16 and FIG. 17 is, however, insufficient in the effect of suppressing the stress ascribable to deformation of the island portion 111 from propagating through the connection members 112 to the frame 103, and still may cause deformation of the lead frames 100 as described in the above.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Embodiments of the present invention will be explained below, referring to the attached drawings. Note that any similar constituents will be given the same reference numerals or symbols in all drawings, and explanations therefor will not be repeated.

### First Embodiment

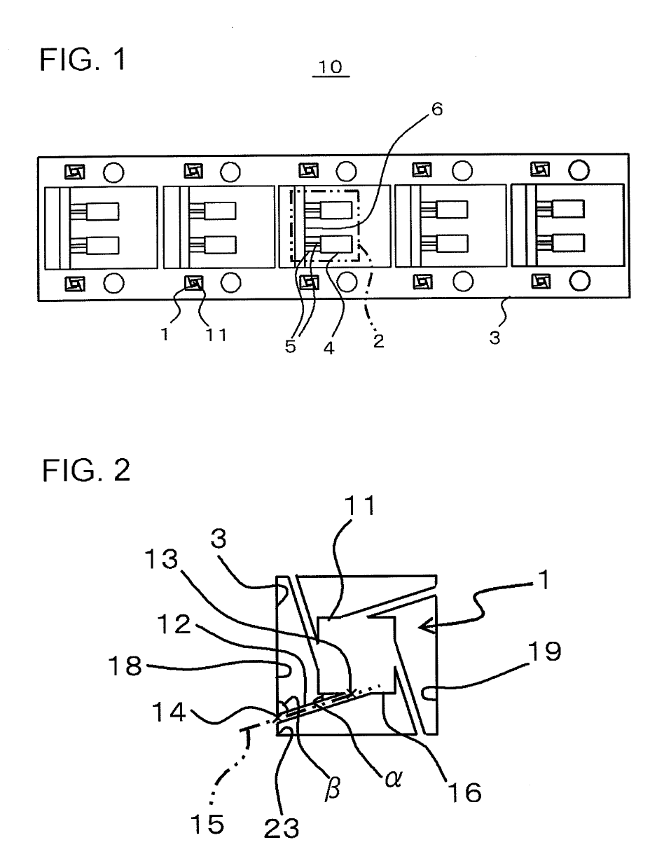

FIG. 1 is a plan view illustrating a lead frame 10 of a first embodiment, and FIG. 2 is an enlarged plan view of the welding portion 1 owned by the lead frame 10 of the first embodiment.

The lead frame 10 of this embodiment has welding portions 1 to be welded to other lead frame 10, and a frame 3. Each welding portion 1 has an island portion 11 provided like an island, and a plurality of connection members 12 which connect the island portion 11 and the frame 3 with each other. A straight line 15, which connects a connection point 13 of the island portion 11 and one connection member 12, and a connection point 14 of such one connection member 12 and the frame 13, inclines away from at least either of a portion of the outer circumference of the island portion 11 where such one connection member 12 is connected (for example in this embodiment, a straight-line edge 16), and a portion of the inner circumference of the frame 3 where such one connection member 12 is connected (for example in this embodiment, a straight-line edge 18). A method of manufacturing a semiconductor device of this embodiment includes: a first step mounting semiconductor elements respectively on the die pads 4 of a first lead frame 10a and a second lead frame 10b, each of which is the lead frame 10 of this embodiment (for example, a light emitting element 82 is mounted on the die pad 4 of the first lead frame 10a, and light receiving element 83 is mounted on the die pad 4 of the second lead frame 10b); a second step stacking the first and second lead frames 10a, 10b, so that the welding portions 1 are aligned with each other, to thereby obtain a two-ply stack; and a third step welding the welding portions 1 thus stacked in the second step. Details will be given below.

First, a configuration of the lead frame 10 will be explained.

The lead frame 10 is used in a form of welded after being two-ply stacked. As illustrated in FIG. 1, the lead frame 10 is configured to have semiconductor device configuring portions 2 each of which configures a part of a semiconductor device (photo-coupler described later, for example), and the frame 3. The semiconductor device configuring portions 2 are disposed at regular intervals in the longitudinal direction of the lead frame 10.

Each semiconductor device configuring portion 2 is configured to have the die pads 4 onto each of which a semiconductor element (for example, a light emitting element 82 or a light receiving element 83 described later) is mounted, leads 5, and a tie bar 6. Each semiconductor device configuring portion 2 has typically two die pads 4. Each die pad 4 is typically connected through, for example, two leads 5 to the tie bar 6.

The thus-configured lead frame 10 has welding portions 1, for the convenience of welding two lead frames 10 with each other after stacking them. The welding portions 1 are provided to the frame 3, and are not included in the semiconductor device configuring portion 2.

The welding portions 1 are disposed on both sides of the individual semiconductor device configuring portions 2, in the direction normal to the longitudinal direction of the lead frame 10.

As illustrated in FIG. 2, each welding portion 1 is configured by a portion inside an opening 19 formed in the frame 3. The welding portion 1 is configured to have the island portion 11 provided like an island, and a plurality of connection members 12 which connect the island portion 11 and the frame 3 with each other, while making the frame 3 hold the island portion 11 in a suspended manner.

In this embodiment, the outer circumference of the island portion 11 and the inner circumference of the opening 19 of the frame 3 respectively has polygonal geometries (more specifically, square for example).

The outer circumference of the island portion 11 and the inner circumference of the opening 19 of the frame 3 are geometrically aligned, for example, in the same orientation. More specifically, the individual edges 16 of the outer circumference of the island portion 11 correspond to the individual edges 18 of the inner circumference of the opening 19 in an one-by-one manner, while keeping every opposed pair of the edge 16 and the edge 18 in parallel with each other.

In this embodiment, each connection member 12 is formed to have a straight-line geometry. The number of connection members 12 in this embodiment is four, for example, per one welding portion 1.

Each connection member 12 typically connects one edge 16 of the outer circumference of the island portion 11, and one edge 18 of the inner circumference of the opening 19, which is adjacent to the edge 18 right opposed to such one edge 16.

Referring now to FIG. 2, the individual connection members 12 are formed so that the straight line 15 which connects “the connection point 13 of the island portion 11 and one connection member 12” and “the connection point 14 of such one connection member 12 and the frame 3” inclines away from (or deflects from the normal direction at) a portion of the outer circumference of the island portion 11 (the edge 16 having a straight profile, in this embodiment) where such one connection member 12 is connected. The individual connection members 12 are formed also so that the straight line 15 inclines away from (or deflects from the normal direction at) a portion of the inner circumference of the opening 19 of the frame 3 (the edge 18 having a straight profile, in this embodiment) where such one connection member 12 is connected.

More specifically, in this embodiment, the island portion 11 is connected, on the edge 16 of the outer circumference thereof, to each connection member 12, wherein the straight line 15 inclines away from the edge 16 of the outer circumference of the island portion 11. On the other hand, the frame 3 is connected, on the inner circumference of the opening 19 thereof, to each connection member 12, wherein the straight line 15 inclines away from the edge 18 of the inner circumference of the opening 19 of the frame 3.

The angle α (smaller angle) formed between the edge 16 and the straight line 15 is preferably 5° or larger and 85° or smaller, for example, and more preferably 15° or larger and 75° or smaller. Similarly, also the angle β (smaller angle) formed between the edge 18 and the straight line 15 is preferably 5° or larger and 85° or smaller, for example, and more preferably 15° or larger and 75° or smaller.

The welding portion 1 has four connection members 12 as described in the above. Each connection member 12 is disposed at a position rotated (360/4)°=90° from every neighboring connection member 12, around the center of said island portion 11 assumed as the center of rotation.

As materials composing the lead frame 10, copper alloy, alloy 42, and ferrous alloy may be adoptable. When the copper alloy is used, the welding portion 1 (in particular, the island portion 11) may have silver plating or the like preliminarily formed thereon, in order to improve wetting to welding. Alternatively, in order to dispense with post-assembly external solder plating, the entire portion of the lead frame 10, or only the semiconductor device configuring portion 2 may be subjected to palladium plating or the like. The semiconductor device configuring portion 2, illustrated in FIG. 1 so as to have two leads 5 per every die pad 4, may alternatively have any other number of leads 5.

Next, a method of manufacturing the lead frame of this embodiment will be explained.

For instance, first, a rolled sheet material (approximately 0.1 to 0.2 mm thick) is formed into the lead frame 10 having a profile as illustrated in FIG. 1, by etching or die punching. The work may optionally be subjected to plating (silver plating onto the welding portion 1, or palladium plating at least onto the semiconductor device configuring portion 2, as described in the above), depending on needs. Alternatively, a sheet material preliminarily plated may be formed into the profile illustrated in FIG. 1, by etching or die punching.

The lead frame 10 illustrated in FIG. 1 may be obtained in this way.

Next, the method of manufacturing the semiconductor device of this embodiment will be explained. Description below will deal with an exemplary case where a photo-coupler is manufactured as the semiconductor device.

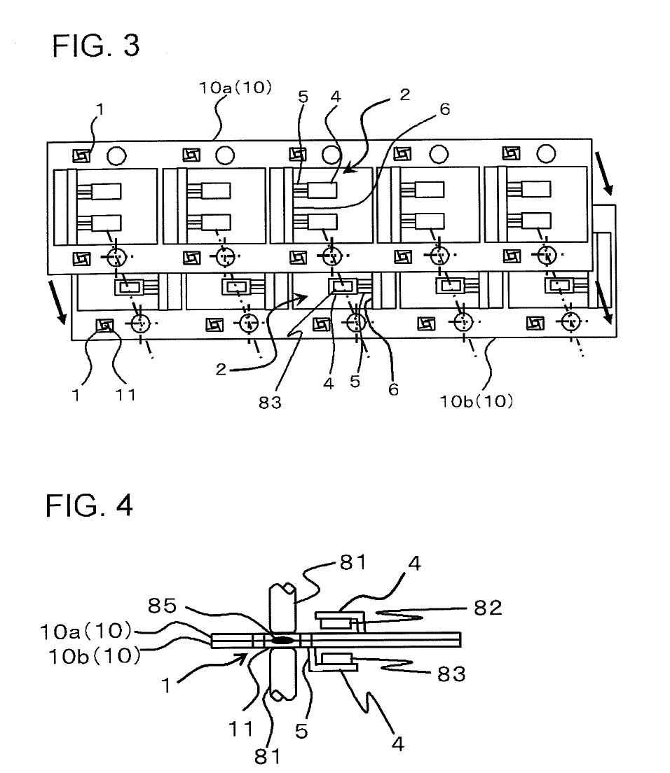

FIG. 3 is a plan view illustrating a state of stacking of two lead frames 10 (10a, 10b), and FIG. 4 is a sectional side elevation illustrating a state of welding of two lead frames 10 (10a, 10b) with each other.

First, the first and second lead frames 10a, 10b, which are respectively the lead frame 10 described in the above, are obtained. One preferable example herein is such that, as illustrated in FIG. 3, the first lead frame 10a and the second lead frame 10b are different from each other only in that the direction of arrangement of the semiconductor device configuring portions 2 is inverted in the longitudinal direction (the transverse direction in FIG. 3). Next, of the first and second lead frame 10a, 10b, the light emitting elements 82 (see FIG. 4) are mounted on the individual die pads 4 of one lead frame 10a, and the light receiving elements 83 (see FIG. 4) are mounted on the individual die pads 4 of the other lead frame 10b.

It is now necessary to arrange each light emitting element 82 and each light receiving element 83 so as to be opposed while being appropriately spaced from each other (see FIG. 4). For this reason, the leads 5 which connect the individual die pads 4 to the tie bars 6 are preliminarily bent for making offset (see FIG. 4), before the light emitting elements 82 or the light receiving elements 83 are mounted on the die pads 4.

Next, as illustrated in FIG. 3 and FIG. 4, two lead frames 10a, 10b are stacked so as to align the individual welding portions 1.

Next, the welding portions 1 thus aligned are welded with each other. More specifically, as illustrated in FIG. 4, a pair of welding electrodes 81 are brought into contact with a pair of island portions 11 of a pair of welding portions 1, so as to supply current therethrough, to thereby effect resistance welding. In the process of current supply, a weld nugget 85 is formed between a pair of island portions 11 stacked with each other, by Joule heat generated in the island portions 111, and thereby the pair of island portions 11 are bonded with each other.

For the case where the lead frames 10 are manufactured using alloy 42 or ferrous alloy having a relatively large electrical resistivity, the welding electrodes 81 (see FIG. 4) used herein are preferably those made of a copper-chromium alloy having a large thermal conductivity, since bulk heat generation in the process of welding is large. On the other hand, for the case where the lead frames 10 are manufactured using a copper alloy having a relatively small bulk electrical resistivity, the welding electrodes 81 used herein are preferably those made of molybdenum having a low thermal conductivity, since the bulk heat generation is small, so that heat generated based on contact resistance between two lead frames 10 is necessarily prevented from dissipating.

Thereafter, the die pads 4 in the semiconductor device configuring portions 2, the light emitting elements 82, the light receiving elements 83 and the leads 5 are encapsulated by a light-transmissive resin (not illustrated). In this way, each light emitting element 82 and each light receiving element 83 are allowed to optically couple with each other, while placing the encapsulation resin composed of the light-transmissive resin in between. The encapsulation resin composed of the light-transmissive resin is further encapsulated using a light-intercepting resin (not illustrated). The semiconductor device configuring portions 2 are then separated from the frame 3 by cutting them at the boundary line therebetween, to thereby obtain the photo-couplers (overall view not shown) as one example of the semiconductor device.

Operations will be explained below.

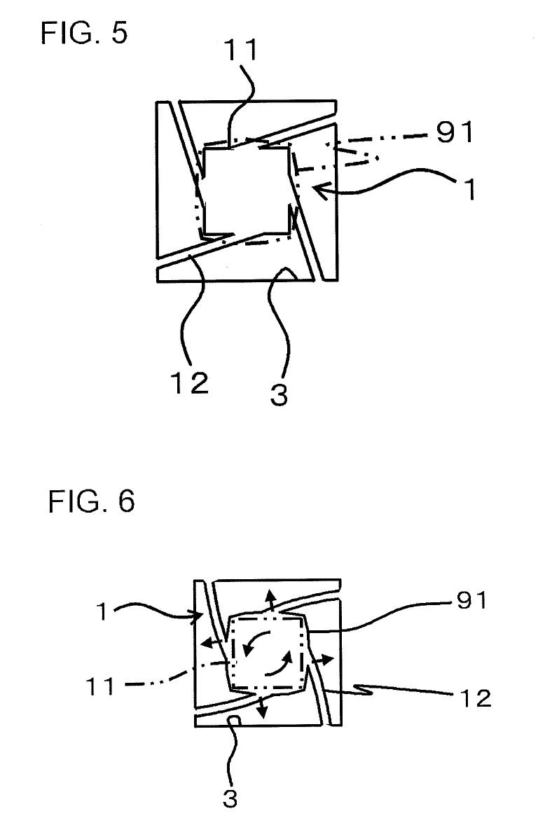

FIG. 5 is a plan view illustrating a state of thermal expansion of the island portion 11 in the process of welding, and FIG. 6 is a plan view explaining a behavior of the welding portion 1 when the island portion 11 causes thermal expansion in the process of welding.

The island portion 11 of the lead frame 10 thermally expands due to Joule heat generated in the process of welding, and deforms so as to extend itself. More specifically, the island portion 11 deforms, by thermal expansion, typically from a geometry indicated by a solid line to a geometry indicated by a two-dot chain line (an post-thermal-expansion island portion, denoted by reference numeral 91) illustrated in FIG. 5.

In the process of deformation from the island portion 11 to the post-thermal-expansion island portion 91, the island portion 11 pushes the connection members 12 outward. However, in this embodiment, the direction of deformation of the island portion 11 does not coincide with the axial direction of the connection members 12, or the direction of the straight line 15 (FIG. 2). Accordingly, the force, which is exerted by the island portion 11 so as to push the connection members 12 outward, deflects the connection members 12 in the direction angled with respect to the straight line 15 (for example, in the direction normal to the straight line 15), as illustrated in FIG. 6. As a result of deflection (bending) of the connection members 12, the island portion 11 rotates as indicated by arrows in FIG. 6.

Since the stress ascribable to thermal expansion of the island portion 11 in the process of welding may thus be absorbed by the deflection of the connection members 12, so that the stress possibly propagated to the frame 3 may be moderated, and thereby the overall deformation of the lead frame 10, excluding the welding portions 1, may be suppressed.

For the case where the semiconductor device is a photo-coupler, it may be important to minimize misalignment of the light emitting element 82 and the light receiving element 83, in order to ensure a satisfactory level of coupling efficiency of light. It is also important to minimize overall deformation of the lead frames 10 after welded, in order to avoid non-conformities in assembly such as unsuccessful feeding and so forth, in view of improving the productivity. According to this embodiment as a measure for coping with the situation, deformation of the lead frame 10 may be suppressed, and thereby misalignment between the light emitting elements 82 and the light receiving elements 83 may be reduced.

Moreover, the deformation of the lead frame 10 caused by the stress ascribable to thermal expansion of the island portion 11 may fully be suppressed, even if the connection members 12 were formed into a straight line geometry as illustrated in FIG. 2, rather than into a winding geometry (S-shape, for example). Since a large space for accommodating the winding connection members (see FIG. 17) is no longer necessary, so that the welding portions 1 may now be arranged only in a small space. As a consequence, the width of the lead frame 10 (vertical dimension in FIG. 1) may be reduced, the lead frame 10 may be downsized, and thereby material cost of the lead frame 10 may be saved.

According to the first embodiment described in the above, the lead frame 10 has the welding portions 1 to be welded to other lead frame 10, and the frame 3. Each welding portion 1 has the island portion 11 provided like an island, and a plurality of connection members 12 which connect the island portion 11 and the frame 3 with each other. A straight line 15, which connects the connection point 13 of the island portion 11 and one connection member 12, and the connection point 14 of such one connection member 12 and the frame 13, inclines away from at least either of the edge 16 which is a portion of the outer circumference of the island portion 11 where such one connection member 12 is connected, and the edge 18 which is a portion of the inner circumference of the frame 3 where such one connections member 12 is connected. Accordingly, the stress ascribable to thermal expansion of the island portion 11 in the process of welding may be absorbed by deflection of the connection members 12. In other words, the stress may be absorbed by the deformation of the connection members 12 in the direction which crosses the straight line at a certain angle (in the normal direction, for example). As a consequence, the stress possibly propagating towards the frame 3 may be moderated, and thereby the overall deformation of the lead frame 10, excluding the welding portions 1, may be suppressed.

More specifically, for example, the overall deformation of the lead frames 10 in the process of welding in the manufacturing of the photo-coupler using two lead frames 10 as described in the above, and waving of the lead frames 10 may be suppressed. Misalignment of the light emitting elements 82 and the light receiving elements 83 may be suppressed. Since the deformation of the lead frames 10 may therefore be suppressed, unsuccessful feeding of the lead frames 10 in the manufacturing facility may be suppressed, and thereby the productivity may be improved, while reducing unacceptable products.

The welding portion 1 has n (n is an integer of 2 or larger, and more specifically 4 for example in this embodiment) connection members 12, and each connection member 12 is disposed at a position rotated (360/n)° (more specifically, 360/4=90° for example in this embodiment) from every neighboring connection member 12, around the center of the island portion 11 assumed as the center of rotation. Accordingly, the island portion 11 may appropriately be rotated (or the connection members 12 are bent) in association with thermal expansion of the island portion 11 in the process of welding, and thereby the stress ascribable to the thermal expansion may be prevented from propagating to the frame 3.

Since the connection members 12 has a straight-line geometry, so that the space for arranging the connection members 12 may be minimized. As a consequence, the width of the lead frame 10 (vertical dimension in FIG. 1) may be minimized, the lead frame 10 may be downsized, and thereby material cost of the lead frame 10 may be saved.

### Second Embodiment

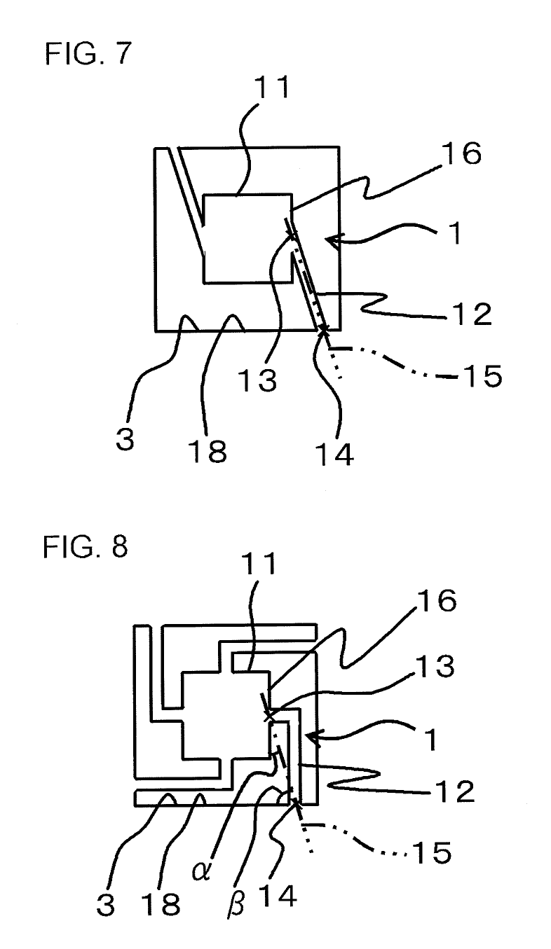

FIG. 7 is an enlarged plan view of the welding portion 1 owned by the lead frame of the second embodiment.

The lead frame of this embodiment is similar to the lead frame 10 of the first embodiment, except for the geometry of the welding portion 1.

In this embodiment, at least any one of edges 16 of the island portion 11 has no connection member 12 connected thereto. More specifically, typically as illustrated in FIG. 7, only two edges of the island portion 11 have the connection members 12 connected thereto. Still more specifically, for example, two these connection members 12 are arranged at the positions rotated (360/2)=180° from each other, around the center of the island portion 11 assumed as the center of rotation.

According to the second embodiment, not only the effects similar to those in the first embodiment, but also effects below will be obtained.

Since the island portion 11 is made more readily rotatable when it causes thermal expansion, by virtue of the reduced number of the connection members 12 which support the island portion 11, so that the thermal stress generated there may more effectively be absorbed by the connection members 12, and thereby the overall deformation of the lead frame may more effectively be suppressed.

### Third Embodiment

FIG. 8 is an enlarged plan view of the welding portion 1 owned by the lead frame of the third embodiment.

The lead frame of this embodiment is similar to the lead frame 10 of the first embodiment, except for the geometry of the connection members 12.

In this embodiment, as illustrated in FIG. 8, the connection members 12 are formed into an L-shape. Angle α formed between the edge 16 and the straight line 15, and angle β formed between the edge 18 and the straight line 15 are defined similarly as described in the first embodiment.

According to the third embodiment, not only the effects similar to those in the first embodiment, but also effects below will be obtained.

In this embodiment, the connection members 12 have a geometry of L-shape which can more readily absorb the deformation than the straight-line connection members 12 can. Accordingly, overall deformation of the lead frame, when the island portion 11 causes thermal expansion, may more effectively be suppressed.

### Fourth Embodiment

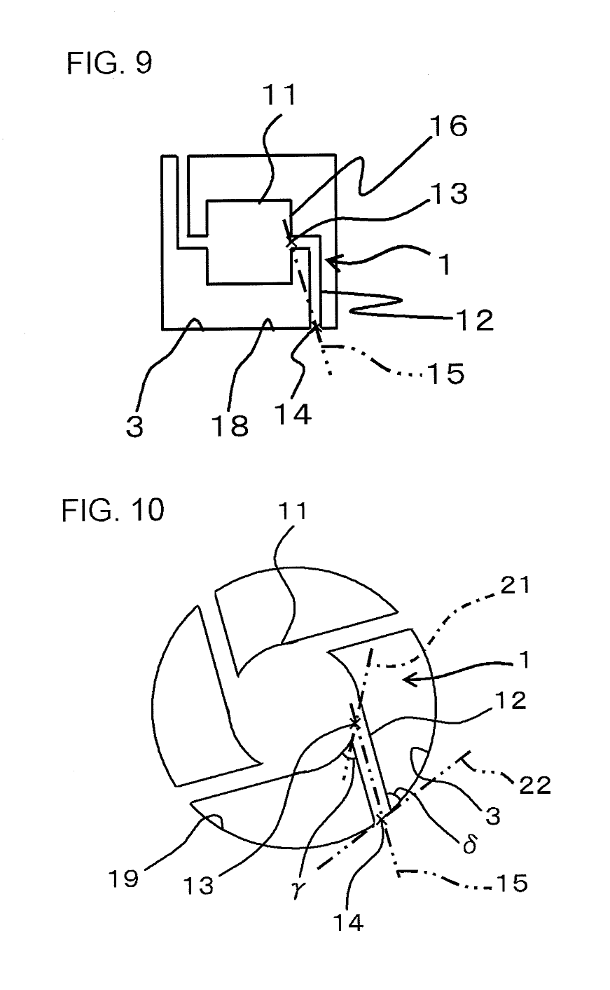

FIG. 9 is an enlarged plan view of the welding portion 1 owned by the lead frame of the fourth embodiment.

The lead frame of this embodiment is similar to the lead frame of the second embodiment, except for the geometry of the connection members 12.

In this embodiment, the connection members 12 are formed into an L-shape, similarly to those in the third embodiment.

According to the fourth embodiment, not only the effects similar to those in the second embodiment, but also effects below will be obtained.

In this embodiment, the connection members 12 have a geometry of L-shape which can more readily absorb the deformation than the straight-line connection members 12 can. Accordingly, overall deformation of the lead frame, when the island portion 11 causes thermal expansion, may more effectively be suppressed. In addition, since the island portion 11 is made more readily rotatable when it causes thermal expansion, by virtue of the reduced number of the connection members 12. According to a synergistic effect of these advantages, the stress generated in the process of thermal expansion of the island portion 11 may more effectively be absorbed, and thereby the overall deformation of the lead frame may more effectively be suppressed.

### Fifth Embodiment

FIG. 10 is an enlarged plan view of the welding portion 1 owned by the lead frame of the fifth embodiment.

The lead frame of this embodiment is similar to the lead frame 10 of the first embodiment, except for the geometry of the welding portion 1, and the geometry of the opening 19 of the frame 3.

As illustrated in FIG. 10, in this embodiment, the outer circumference of the island portion 11, and the inner circumference of the opening 19 of the frame 3 respectively have curved geometries (more specifically, circular geometries). The circular outer circumference of the island portion 11 and the circular inner circumference of the opening 19 of the frame 3 are arranged in a concentric manner.

Each connection member 12 connects the curved (circular, for example) outer circumference of the island portion 11 and the curved (circular, for example) inner circumference of the opening 19 with each other.

As illustrated in FIG. 10, the individual connection members 12 are formed so that the straight line 15 which connects the “connection point 13 of the island portion 11 and one connection member 12” and “the connection point 14 of such one connection member 12 and the frame 3” inclines away from (or deflects from the normal direction at) a portion of the outer circumference of the island portion 11 where such one connection member 12 is connected. In other words, the island portion 11 is connected to each connection member 12 at the curved portion of the outer circumference thereof, and the straight line 15 inclines away from a tangential line 21 on the outer circumference of the island portion 11, at the connection point 13 of each connection member 12 and the island portion 11.

The individual connection members 12 are formed also so that the straight line 15 inclines away from (or deflects from the normal direction at) a portion of the inner circumference of the frame 3 where such one connection member 12 is connected. In other words, the frame 3 is connected to each connection member 12 at the curved portion of the inner circumference thereof, and the straight line 15 inclines away from a tangential line 22 on the inner circumference of the frame 3, at the connection point 14 of each connection member 12 and the frame 3.

The angle γ (smaller angle) formed between the tangential line 21 and the straight line 15 is preferably 5° or larger and 85° or smaller for example, and more preferably 15° or larger and 75° or smaller. Similarly, also the angle δ (smaller angle) formed between the tangential line 22 and the straight line 15 is preferably 5° or larger and 85° or smaller for example, and more preferably 15° or larger and 75° or smaller.

Also in this embodiment, the welding portion 1 has four connection members 12, wherein each connection member 12 is disposed at a position rotated, for example, (360/4)°=90° from every neighboring connection member 12, around the center of the island portion 11 assumed as the center of rotation.

According to the fifth embodiment, not only the effects similar to those in the first embodiment, but also effects below will be obtained.

By making the geometry of the opening 19 of the frame 3 into a curved one (circular geometry, for example), the stress possibly applied from the connection members 12 to the frame 3 may be prevented from concentrating at the corners 23 of the frame 3 (see FIG. 2). In short, an effect of dispersing the stress may be expectable, and thereby the overall deformation of the lead frame may more effectively be suppressed.

### Sixth Embodiment

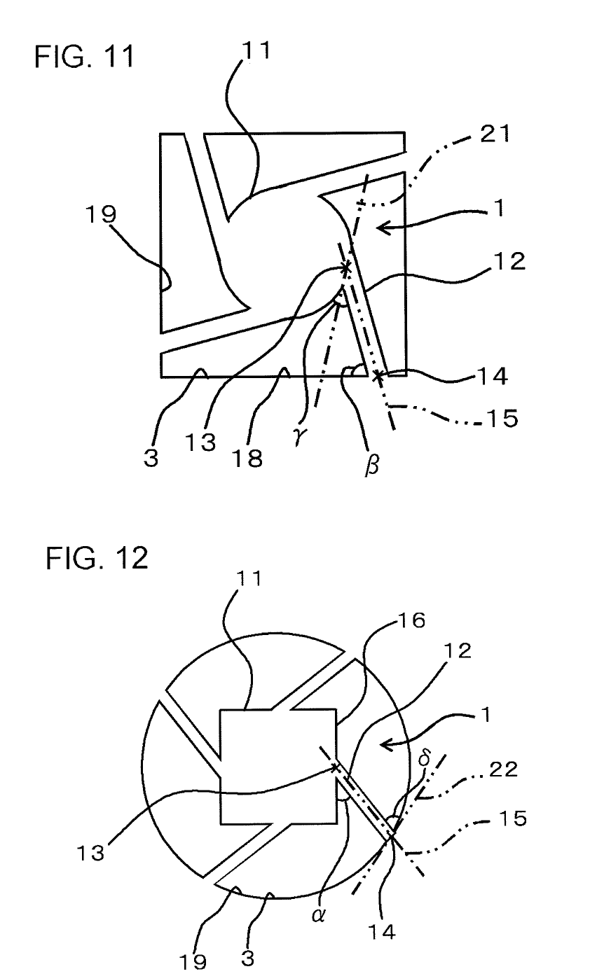

FIG. 11 is an enlarged plan view of the welding portion 1 owned by the lead frame of the sixth embodiment.

The lead frame of this embodiment is similar to the lead frame of the fifth embodiment, except for the geometry of the opening 19 of the frame 3.

As illustrated in FIG. 11, in this embodiment, the inner circumference of the opening 19 of the frame 3 has a polygonal geometry (more specifically, square geometry, for example), similarly as described in the first embodiment. The island portion 11 herein is typically arranged at the center of the opening 19. The angle β formed between the edge 18 and the straight line 15, and the angle γ formed between the tangential line 21 and the straight line 15 are defined similarly as described in the first embodiment and the fifth embodiment, respectively.

According to the sixth embodiment, the effects similar to those in the first embodiment may be obtained.

### Seventh Embodiment

FIG. 12 is an enlarged plan view of the welding portion 1 owned by the lead frame of the seventh embodiment.

The lead frame of this embodiment is similar to the lead frame of the fifth embodiment, except for the geometry of the outer circumference of the island portion 11.

As illustrated in FIG. 12, in this embodiment, the outer circumference of the island portion 11 has a polygonal geometry (more specifically, square geometry, for example), similarly as described in the first embodiment. The island portion 11 herein is typically arranged at the center of the opening 19. The angle α formed between the edge 16 and the straight line 15, and the angle δ formed between the tangential line 22 and the straight line 15 are defined similarly as described in the first embodiment and the fifth embodiment, respectively.

According to the seventh embodiment, the effects similar to those in the fifth embodiment may be obtained.

### Eighth Embodiment

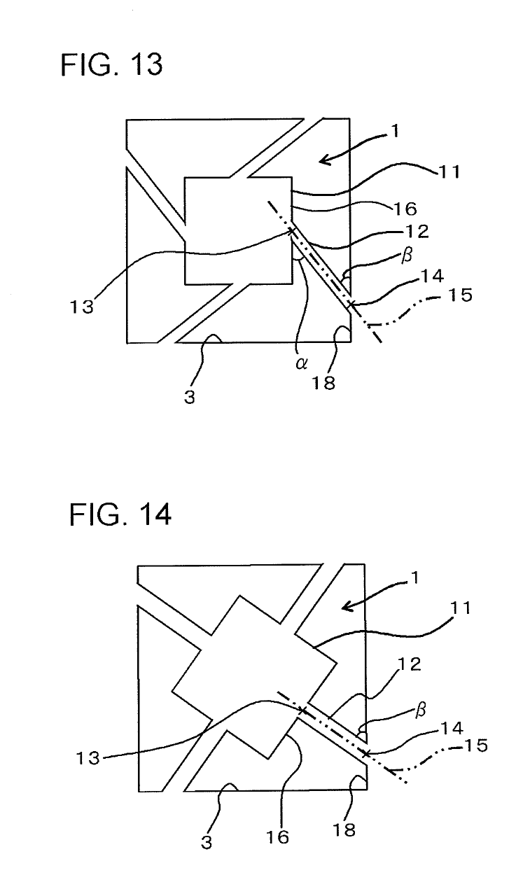

FIG. 13 is an enlarged plan view of the welding portion 1 owned by the lead frame of the eighth embodiment.

The lead frame of this embodiment is similar to the lead frame 10 of the first embodiment, except for the geometry of the welding portion 1.

In first embodiment, each connection member 12 connects one edge 16 of the outer circumference of the island portion 11, and one edge 18 of the inner circumference of the opening 19, which is adjacent to the edge 18 right opposed to such one edge 16.

In contrast, in the eighth embodiment, each connection member 12 connects one edge 16 of the outer circumference of the island portion 11, and one edge 18 of the inner circumference of the opening 19, which is right opposed to such one edge 16, with each other.

The angle α formed between the edge 16 and the straight line 15, and the angle β formed between the edge 18 and the straight line 15 are defined similarly as described in the first embodiment.

According to the eighth embodiment, the effects similar to those in the first embodiment may be obtained.

### Ninth Embodiment

FIG. 14 is an enlarged plan view of the welding portion 1 owned by the lead frame of the ninth embodiment.

The lead frame of this embodiment is similar to the lead frame 10 of the first embodiment, except for the geometry of the welding portion 1.

In the first embodiment, an exemplary case where the straight line 15 inclines from the edge 16 of the outer circumference of the island portion 11 was described. In contrast, in this embodiment, the straight line 15 crosses normal to the edge 16.

The angle β formed between the edge 18 and the straight line 15 is defined similarly as described in the first embodiment.

According to the ninth embodiment, the effects similar to those in the first embodiment may be obtained.

### Tenth Embodiment

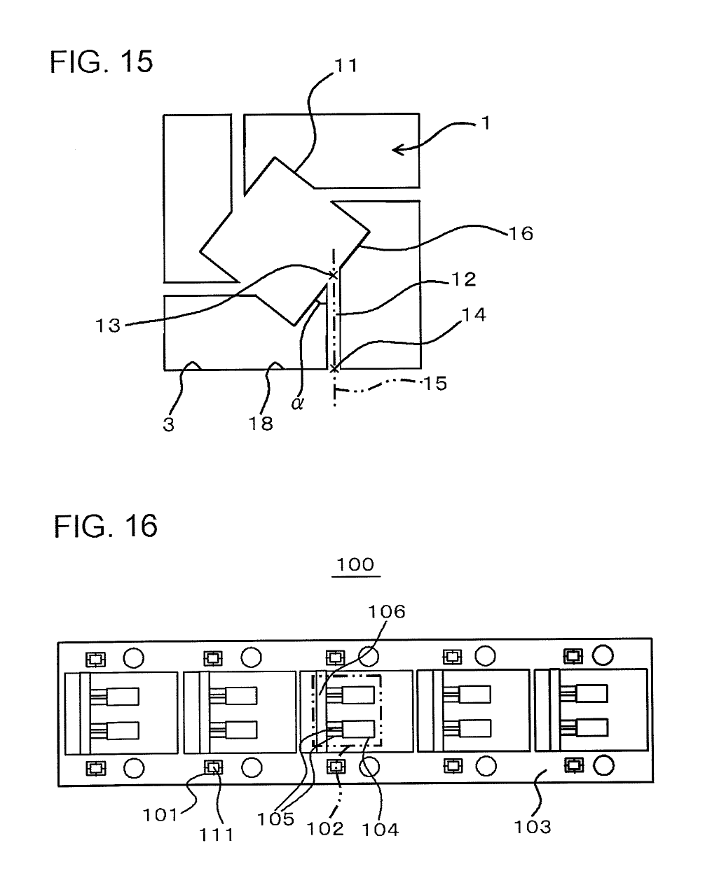

FIG. 15 is an enlarged plan view of the welding portion 1 owned by the lead frame of the tenth embodiment.

The lead frame of this embodiment is similar to the lead frame 10 of the first embodiment, except for the geometry of the welding portion 1.

In the first embodiment, an exemplary case where the straight line 15 inclines from the edge 18 of the inner circumference of the frame 3 was described. In contrast, in this embodiment, the straight line 15 crosses normal to the edge 18.

The angle α formed between the edge 16 and the straight line 15 is defined similarly as described in the first embodiment.

According to the tenth embodiment, the effects similar to those in the first embodiment may be obtained.

The connection members 12, having been exemplified as those having the L-shape and straight geometries in the embodiments above, may have any other geometries such as S-shape, Z-shape, arc and so forth.

The outer circumference of the island portion 11 and the inner circumference of the opening 19 of the frame 3, having been exemplified as those having the square and circular geometries in the embodiments above, may have any other geometries, such as rectangle or quadrangle other than square; polygonal geometries (triangle, pentagon, hexagon, and so forth) other than quadrangle; other geometries containing straight-line edge; and curved geometries other than circle (such as ellipse, oval, and other geometries containing curve). Moreover, the geometry of the outer circumference of the island portion 11 may contain straight-line portion and the residual curved portion, wherein independent connection members 12 may be connected respectively to the straight portion and the curved portion. Similarly, the geometry of the inner circumference of the opening 19 of the frame 3 may contain straight-line portion and the residual curved portion, wherein independent connection members 12 may be connected respectively to the straight portion and the curved portion.

It is apparent that the present invention is not limited to the above embodiments, that may be modified and changed without departing from the scope and spirit of the invention.

What is claimed is:

1. A lead frame comprising a welding portion to be welded to other lead frame, and a frame,
said welding portion having an island portion provided like an island, and a plurality of connection members which connect said island portion and said frame with each other, and
one connection member being provided so that a straight line which connects a connection point of said island portion and said one connection member, and a connection point of said one connection member and said frame, inclines away from at least either of a portion of the outer circumference of said island portion where said one connection member is connected, and a portion of the inner circumference of said frame where said one connection member is connected.

2. The lead frame as claimed in claim 1, wherein said outer circumference of said island portion has a straight portion, said one connection member is connected to said straight portion, and said straight line inclines away from said straight portion.

3. The lead frame as claimed in claim 2, wherein said outer circumference of said island portion has a polygonal geometry.

4. The lead frame as claimed in claim 1,
wherein said outer circumference of said island portion has a curved portion, said one connection member is connected to said curved portion, and said straight line inclines away from the tangential line on said curved portion, at the connection point of said curved portion and said one connection member.

5. The lead frame as claimed in claim 4,
wherein said outer circumference of said island portion has a circular geometry.

6. The lead frame as claimed in claim 1,
wherein said inner circumference of said frame has a straight portion, said one connection member is connected to said straight portion, and said straight line inclines away from said straight portion.

7. The lead frame as claimed in claim 6,
wherein said inner circumference of said frame has a polygonal geometry.

8. The lead frame as claimed in claim 1,
wherein said inner circumference of said frame has a curved portion, said one connection member is connected to said curved portion, and said straight line inclines away from the tangential line on said curved portion, at the connection point of said curved portion and said one connection member.

9. The lead frame as claimed in claim 8,
wherein said inner circumference of said frame has a circular geometry.

10. The lead frame as claimed in claim 1,
wherein said welding portion has n (n is an integer of 2 or larger) connection members, and
said connection member is disposed at a position rotated (360/n)° from every neighboring connection member, around the center of said island portion assumed as the center of rotation.

11. The lead frame as claimed in claim 1,
wherein said connection member has a straight line geometry.

12. The lead frame as claimed in claim 1,
wherein said connection member has an L-form geometry.

13. A method of manufacturing a semiconductor device comprising:
a first step mounting semiconductor elements respectively on the die pads of a first lead frame and a second lead frame, each of which is the lead frame described in claim 1;
a second step stacking said first and second lead frames, so that said welding portions are aligned with each other, to thereby obtain a two-ply stack; and
a third step welding said welding portions thus stacked in said second step.
